(19) United States
(12) Patent Application Publication
(10) Pub. No.: US 2010/0159132 A1
(43) Pub. Date: Jun. 24, 2010

(54) Linear Deposition Source

(75) Inventors: Chad Conroy, Stillwater, MN (US); Scott Wayne Priddy, Saint Loius Park, MN (US); Jacob Allan Dahlstrom, Cottage Grove, MN (US); Richard Charles Bresnahan, Cottage Grove, MN (US); David William Gotthold, Lino Lakes, MN (US); John Charles Patrin, Chanhassen, MN (US)

Correspondence Address: RAUSCHENBACH PATENT LAW GROUP, LLP, P.O. BOX 387, BEDFORD, MA, 01730, US

(73) Assignee: VEECO INSTRUMENTS, INC., Plainview, NY (US)

(21) Appl. No.: 12/628,189

(22) Filed: Nov. 30, 2009

Related U.S. Application Data
(60) Provisional application No. 61/156,348, filed on Feb. 27, 2009.
(60) Provisional application No. 61/138,932, filed on Dec. 18, 2008.

(51) Int. Cl. C23C 16/44; C23C 16/00

(52) U.S. Cl. 427/248.1; 118/726

(57) ABSTRACT

A deposition source includes a plurality of crucibles that each contains a deposition material. A heat shield provides at least partial thermal isolation for at least one of the plurality of crucibles. A body is included with a plurality of conductance channels. An input of each of the plurality of conductance channels is coupled to an output of a respective one of the plurality of crucibles. A heater increases a temperature of the plurality of crucibles so that each crucible evaporates the deposition material into the plurality of conductance channels. An input of each of a plurality of nozzles is coupled to an output of one of the plurality of conductance channels. Evaporated deposition materials are transported from the crucibles through the conductance channels to the nozzles where the evaporated deposition material is ejected from the plurality of nozzles to form a deposition flux.

### RELATED APPLICATION SECTION

This application claims priority to both U.S. Provisional Patent Application Ser. No. 61/156,348 filed Feb. 27, 2009, entitled “Deposition Sources, Systems, and Related Methods for Co-Depositing Copper, Indium, and Gallium,” and U.S. Provisional Application Ser. No. 61/138,932 filed Dec. 18, 2008, entitled “Deposition Sources, Systems, and Related Methods for Co-Depositing Copper, Indium, and Gallium.” The entire specification of U.S. Provisional Application Ser. No. 61/156,348 and U.S. Provisional Application Ser. No. 61/138,932 are incorporated herein by reference.

The section headings used herein are for organizational purposes only and should not to be construed as limiting the subject matter described in the present application in any way.

### INTRODUCTION

Large area substrate deposition systems have been used for processing flexible web substrates and rigid panel substrates of numerous types of substrate materials for many years. Many known systems are designed to process plastic web substrates and rigid panel glass substrates. The web substrates or rigid panels are passed directly above a linear deposition source. Known linear deposition sources that are suitable for evaporating materials on a web substrate or on a rigid panel substrate include a boat-shaped crucible, which is typically formed of a refractory material for containing deposition source materials. The crucible is placed in the interior of a vapor outlet tube. The vapor outlet tube functions simultaneously as a vaporizing space and as a space to distribute the vapors. One or more vapor outlet openings are arranged linearly along the source.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the teaching. The drawings are not intended to limit the scope of the teachings in any way.

FIG. 1 illustrates a perspective cross-sectional view of a linear deposition source according to the present invention that includes a plurality of crucibles coupled to a plurality of conductance channels and then to a plurality of nozzles in a linear configuration.

FIG. 2A illustrates a cross-sectional view of the linear deposition source according to the present invention with the plurality of nozzles positioned so that they evaporate deposition material in an upward direction.

FIG. 2B illustrates a cross-sectional view of a linear deposition source according to the present invention with the plurality of nozzles positioned so that they evaporate deposition material in a downward direction.

FIG. 2C illustrates a cross-sectional view of a linear deposition source according to the present invention with the body including the plurality of nozzles positioned in a vertical direction.

FIG. 2D illustrates a cross-sectional view of another linear deposition source according to the present invention with the body including the plurality of nozzles positioned in a vertical direction.

FIG. 3 illustrates a perspective cross-sectional view of a linear deposition source according to the present invention that includes a single crucible coupled to a plurality of conductance channels and then to a plurality of nozzles in a linear configuration.

FIG. 4 illustrates a perspective cross-sectional view of a crucible for the linear deposition source of the present teaching that is formed of two types of materials.

FIG. 5 illustrates a perspective top view of a portion of the linear deposition source according to the present invention that shows the three conductance channels coupled to three crucibles in the housing.

FIG. 6A is a perspective view of a portion of a resistive crucible heater for the linear deposition source of the present invention that shows the inside and three sides of the heater where the crucible is positioned.

FIG. 6B is a perspective view of an outside of one of the plurality of crucible heaters for heating each of the plurality of crucibles.

FIG. 7A is a side view of a linear deposition source according to the present invention that shows conductance channel heaters for heating the plurality of conductance channels.

FIG. 7B is a perspective view of the rods comprising the conductance channel heaters.

FIG. 7C illustrates a perspective view of the body of a linear deposition source according to the present invention that shows a coupling which joins the end of the rods to the body.

FIG. 8 illustrates the frame of the body that includes an expansion link.

FIG. 9A is a perspective cross-sectional view of a heat shield for the plurality of crucibles and for the plurality of conductance channels of a linear deposition source according to the present teaching.

FIG. 9B is a full perspective view of the heat shield shown in FIG. 9A.

FIG. 10 illustrates a top perspective view of a deposition source according to the present teaching that shows the plurality of nozzles in the body for emitting evaporated materials onto substrates or other workpieces.

FIG. 11A illustrates a cross-sectional view of the body of the deposition source according to the present teaching that shows a column of nozzles coupled to a conductance channel with tubes that control the flow of deposition material to the nozzles.

FIG. 11B illustrates a cross-sectional view of the plurality of conductance channels of the deposition source according to the present teaching that shows a row of nozzles coupled to the plurality of conductance channel with tubes that control the flow of deposition material to the nozzles.

FIG. 12 illustrates a perspective view of a nozzle comprising one of the plurality of nozzles for a linear deposition source according to the present teaching.

### DESCRIPTION OF VARIOUS EMBODIMENTS

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the methods of the present teachings may be performed in any order and/or simultaneously as long as the teaching remains operable. Furthermore, it should be understood that the apparatus and methods of the present teachings can include any number or all of the described embodiments as long as the teaching remains operable.

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

The present teaching relates generally to apparatus and methods for producing a flux of source material vapor for deposition on a substrate. Some aspects of the present teaching relate to linear deposition sources that are suitable for producing a flux of source material vapor for depositing material on a web substrate, a rigid panel substrate, or another type of an elongated workpiece. Other aspects of the present teaching relate to linear deposition sources that are suitable for producing a flux of source material vapor for depositing material on a substrate holder that supports a plurality of conventional substrates, such as semiconductor substrates.

In many embodiments of the present teaching, the methods and apparatus relate to deposition by evaporation. The term “evaporation” as used herein means to convert the source material to a vapor and includes the normal use of several terms in the art, such as evaporation, vaporization, and sublimation. The source material being converted to a vapor can be in any state of matter. In many embodiments, the apparatus and method of the present teaching are used to co-evaporate two or more different materials onto a substrate, such as a web substrate or a rigid panel substrate. In some embodiments, the apparatus and method of the present teaching are used to evaporate a single material onto a substrate, such as a web substrate or a rigid panel substrate.

One application of the present teaching relates to methods and apparatus for co-deposition of copper, indium, and gallium onto a web substrate or a rigid panel substrate. Compounds of copper indium diselenide (CIS compounds) that have gallium substituted for all or part of the indium are known as copper indium gallium diselenide compounds (CIGS compounds). CIGS compounds are commonly used to fabricate photovoltaic cells. In particular, CIGS compounds are commonly used as absorber layers in thin-film solar cells. These CIGS compounds have a direct band gap which permits strong absorption of solar radiation in the visible region of the electromagnetic spectrum. CIGS photovoltaic cells have been demonstrated to have high conversion efficiencies and good stability as compared to commonly used photovoltaic cells with other types of absorber layer compounds, such as cadmium telluride (CdTe) and amorphous silicon (a-Si).

CIGS absorbing layers are typically p-type compound semiconductor layers with good crystallinity. Good crystallinity is generally required to achieve desired charge transport properties necessary for high efficiency photovoltaic operation. In practice, the CIGS absorbing layer must be at least partially crystallized in order to achieve high efficiency photovoltaic operation. Crystallized CIGS compounds have a crystallographic structure which can be characterized as either chalcopyrite or sphalerite depending on the deposition temperature used to form the CIGS compound.

CIGS compounds can be formed by various techniques. One method for forming CIGS compounds uses chemical precursors. The chemical precursors are deposited in thin films and are then subsequently annealed to form the desired CIGS layer. When CIGS precursor materials are deposited at a low temperature, the resulting CIGS thin films are amorphous or only weakly crystallized. The CIGS thin films are then annealed at elevated temperatures to improve the crystallization of the CIGS compound in order to provide the desired charge transport properties.

However, at the elevated temperatures necessary to cause partial crystallization of the CIGS thin films, the selenium in the deposited thin film is more volatile than the other elements. Consequently, selenium is often added while annealing the precursor layers to improve crystallized and to provide the CIGS compound with the desired composition and stoichiometry. This method of forming CIGS thin film compounds is relatively time consuming and requires large volumes of selenium in the vapor phase, which adds to the manufacturing costs.

Another method for forming CIGS compounds uses vacuum evaporation. CIGS photovoltaic cells fabricated by co-evaporation can have high photovoltaic conversion efficiencies compared to CIGS photovoltaic cells fabricated with precursor materials. In this method, copper, indium, gallium, and selenium are co-evaporated onto a substrate. Co-evaporation allows for precise control of the thin film stoichiometry and allows for compositional grading in the thin film light-absorbing layer. Therefore, co-evaporation can be used to precisely tailor the bandgap in order to achieve optimum photovoltaic performance. However, co-evaporation of copper, indium, gallium, and selenium is a process technique that can be difficult to use on an industrial scale because it is difficult to evaporate materials uniformly over large surface areas.

One aspect of the present teaching is to provide deposition sources, systems, and methods of operating such sources and systems to efficiently and controllably provide multiple vaporized source materials for fabrication of numerous types of devices, such as CIGS photovoltaic cells. Another aspect of the present teaching is to provide deposition sources, systems, and methods of operating such sources and systems to efficiently and controllably provide a single vaporized source material for fabrication of numerous types of devices, such as organic light-emitting diode (OLED) devices. One skilled in the art will appreciate that although some aspects of the present teachings are described in connection with the fabrication of CIGS photovoltaic cells and OLED devices, the teachings in this disclosure apply to any other type of device that can be fabricated using evaporated materials.

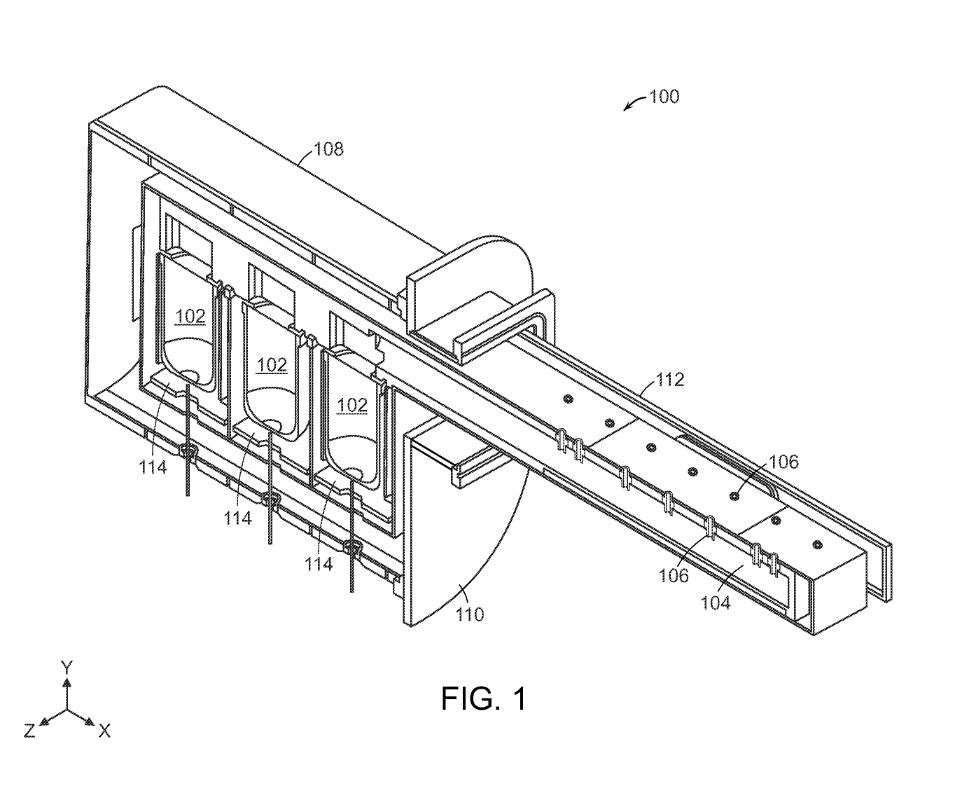

FIG. 1 illustrates a perspective cross-sectional view of a linear deposition source 100 according to the present invention that includes a plurality of crucibles 102 coupled to a plurality of conductance channels 104 and then to a plurality of nozzles 106 in a linear configuration. Each of the plurality of crucibles 102 contains an evaporation source material, which may be the same or a different source material. An input of each of the plurality of conductance channels 104 is coupled to an output of a respective one of the plurality of crucibles 102. In many embodiments, the plurality of conductance channels 104 is designed so that there is no intermixing of evaporated materials while the evaporated materials are being transported in the plurality of conductance channels 104.

A housing 108 contains the plurality of crucibles 102. The housing 108 is formed of stainless steel or a similar material. In some embodiments, fluid cooling channels are positioned along the housing 108. The housing 108 also includes a sealing flange 110 that attaches the housing 108 to a vacuum chamber (not shown). One feature of the linear deposition source 100 is that the crucibles are outside of the vacuum chamber and, therefore, they are easily refilled and serviced, thereby increasing availability. A body 112 including the plurality of conductance channels 104 and the plurality of nozzles 102 extends past the sealing flange 110 of the housing 108. In some embodiments, fluid cooling channels are positioned along the body 112.

In the embodiment shown in FIG. 1, the source 100 includes three crucibles 102 in a linear configuration with inputs of respective ones of the three conductance channels 104 being coupled to outputs of respective ones of the three crucibles 102. The nozzles 106 are positioned at a plurality of locations along each of the plurality of conductance channels 104. However, because FIG. 1 is a cross-sectional view, only the middle conductance channel 104, and one half the nozzles 106 are shown in FIG. 1.

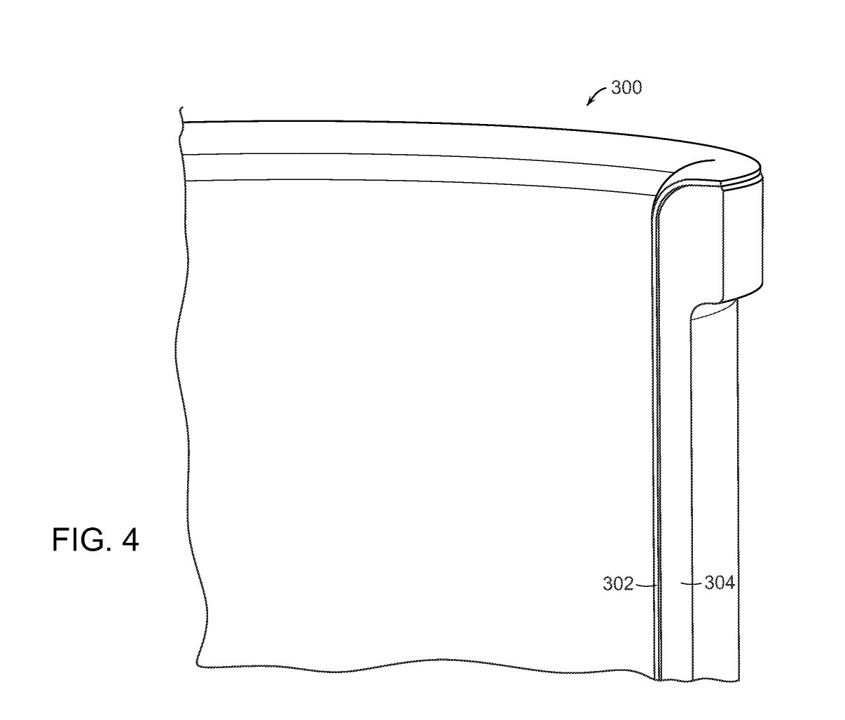

One skilled in the art will appreciate that numerous types of crucibles can be used. For example, at least some of the plurality of crucibles can include at least one crucible formed inside another crucible as described in connection with FIG. 4. The plurality of crucibles 102 contains evaporation material suitable for the particular fabrication process. In many embodiments, each of the plurality of crucibles 102 contains a different evaporation material. For example, each of the three crucibles can contain one of copper, indium, and gallium so as to provide a material source for efficiently co-evaporating a functional absorbing layer of a CIGS based photovoltaic device. However, in some embodiments, at least two of the plurality of crucibles contains the same deposition material. For example, each of the three crucibles can contain a single material system for depositing contacts for OLED devices.

One or more crucible heaters 114 are positioned in thermal communication with the plurality of crucibles 102. The crucible heaters 114 are designed and positioned to increase the temperature of the plurality of crucibles 102 so that each of the plurality of crucibles 102 evaporates its respective deposition source material into a respective one of the plurality of conductance channels 104. Some crucible heaters 114 are required to heat the evaporation source material to very high temperatures. Such crucible heaters can be formed of graphite, silicon carbide, refractory materials, or other very high melting point materials. The crucible heaters 114 can be one single heater or can be a plurality of heaters. For example, in one embodiment, each of a plurality of crucible heaters is individually controllable so that a respective one of the plurality of crucible heaters is in thermal communication with a respective one of each of the plurality of crucibles 102.

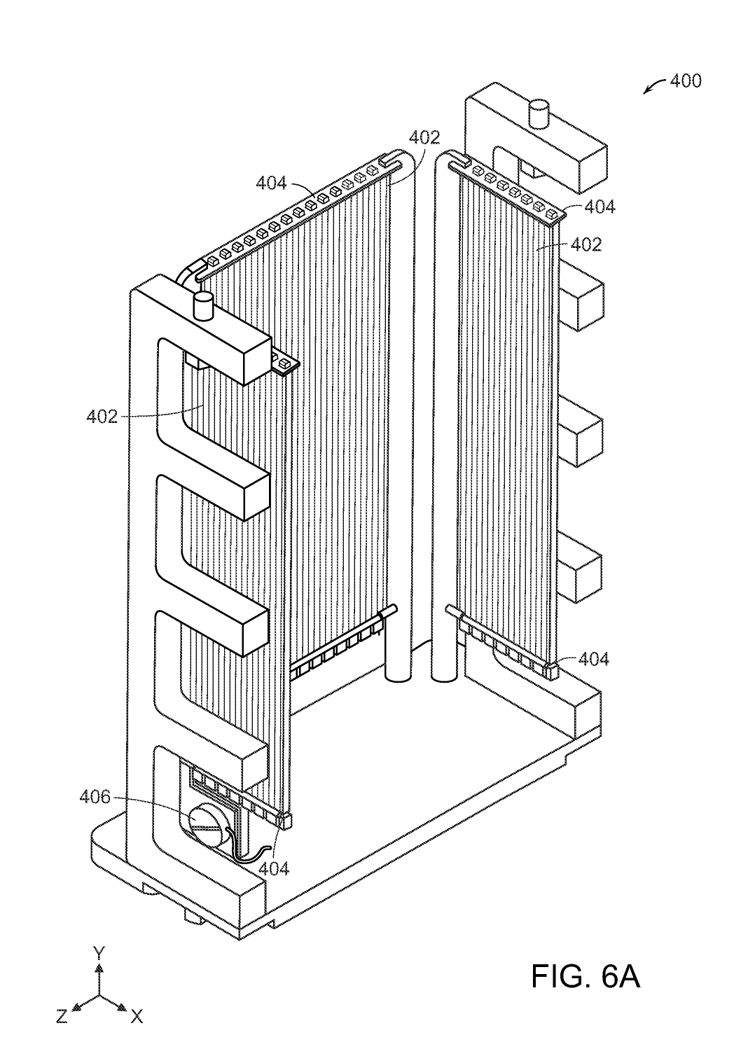

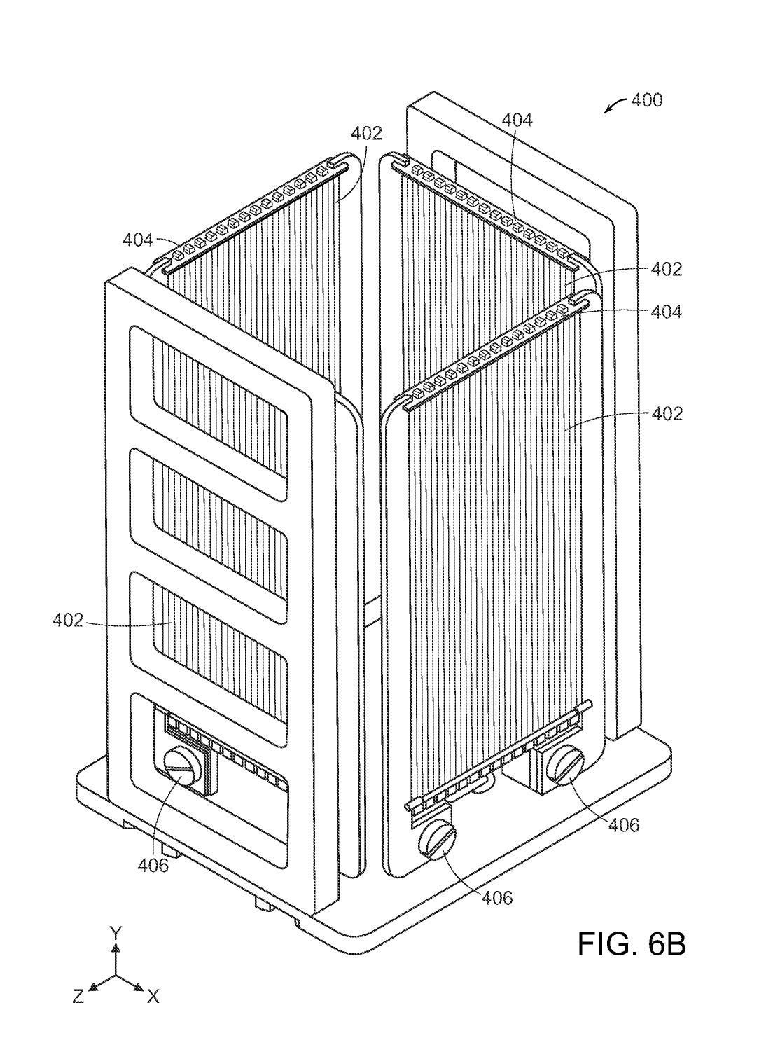

The crucible heaters 114 can be any type of heater. For example, the crucible heaters 114 can be resistive heaters as shown in FIG. 1. One embodiment of a resistive heater is described in more detail in connection with FIGS. 6A and 6B. The crucible heaters 114 can also be one of numerous types of RF induction heaters and/or infrared heaters. In many embodiments, all the crucible heaters 114 are the same type of heater. However, in some embodiments, two or more of the crucible heaters 114 are different types of heaters that have different thermal properties for evaporating different deposition source materials.

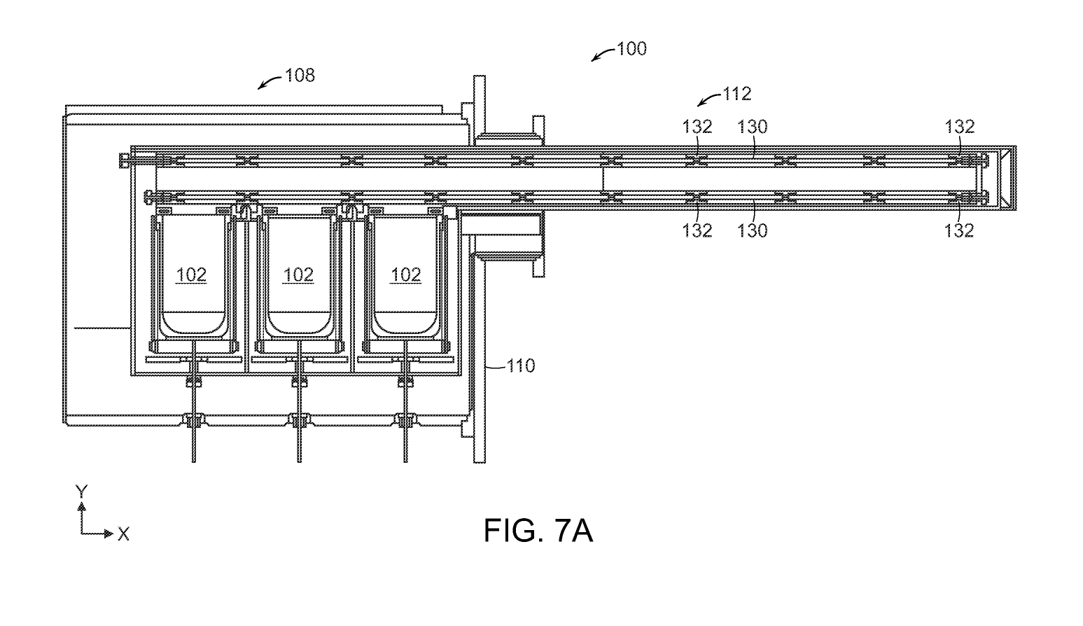

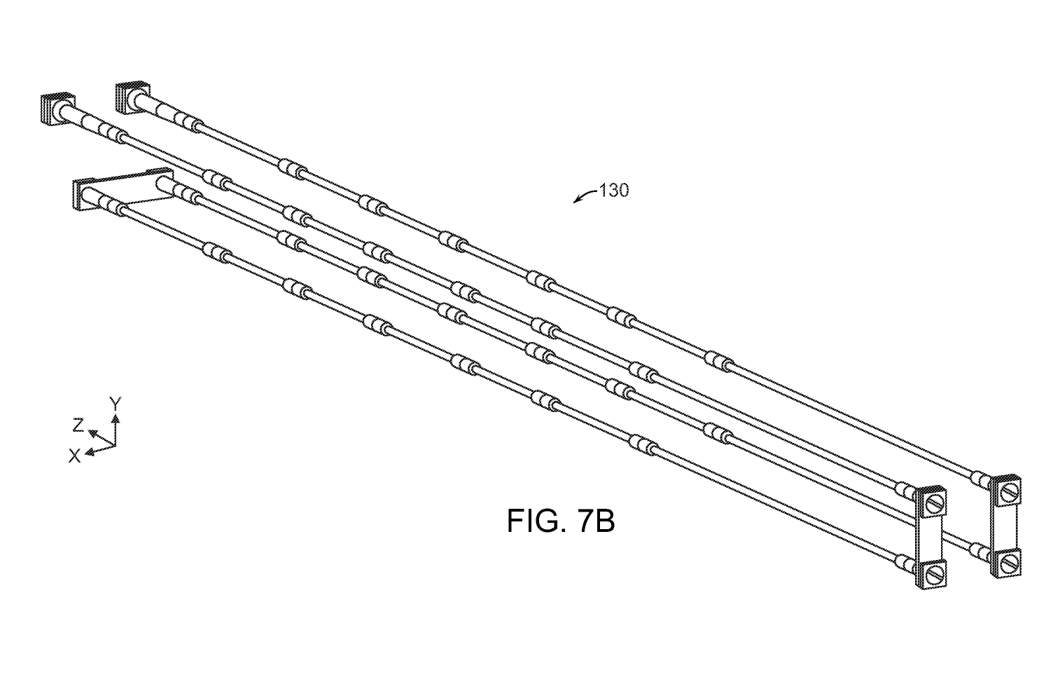

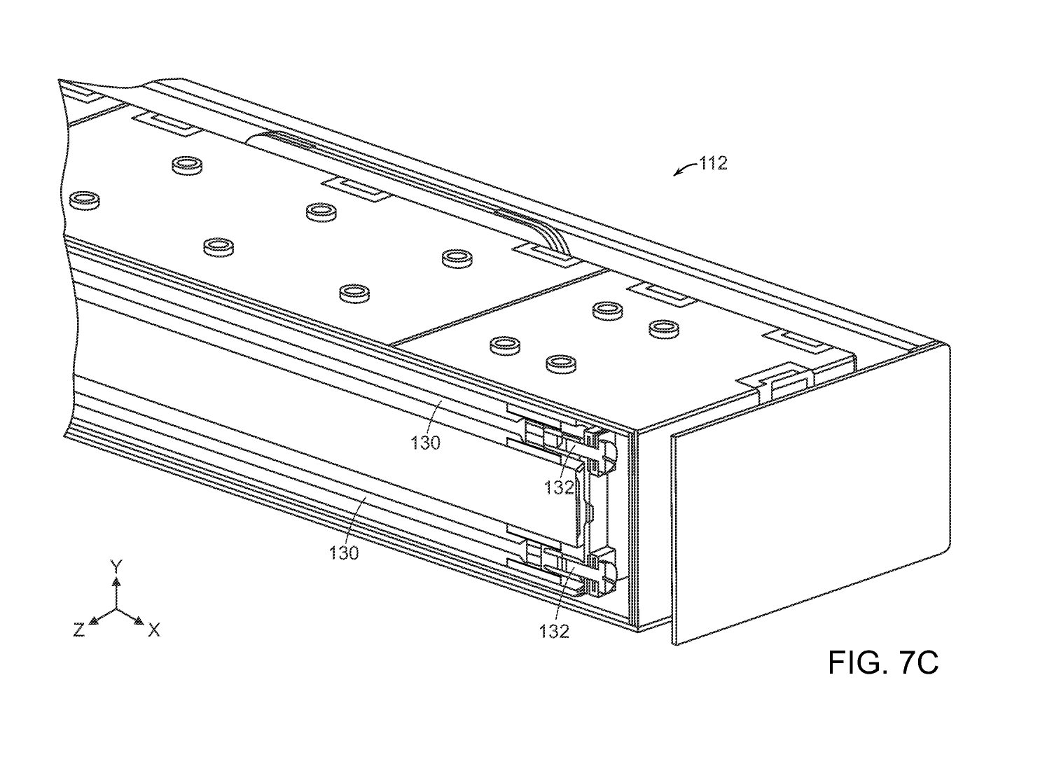

The crucible heaters 114 or separate conductance channel heaters are positioned in thermal communication with at least one of the plurality of conductance channels 104 so that the temperature of each of the plurality of conductance channels 104 is raised above the condensation point of deposition source materials passing through the particular conductance channel. Conductance channel heaters are described in connection with FIGS. 7A, 7B and 7C. One skilled in the art will appreciate that numerous types of heaters can used to heat the plurality of conductance channels 104, such as resistive heaters, RF induction heaters, and/or infrared heaters. The conductance channel heater can be a single heater or can be a plurality of heaters. More than one type of heater can be used. In one embodiment, the conductance channel heater has the capability of controlling a temperature of one of the plurality of conductance channels 104 relative to another one of the plurality of conductance channels 104.

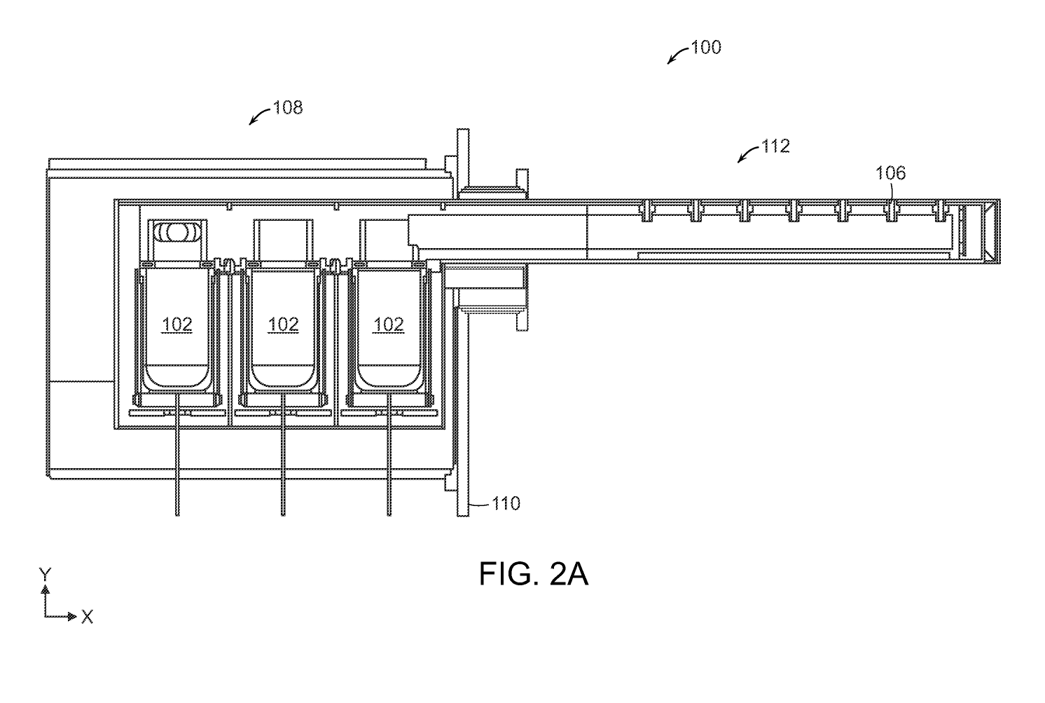

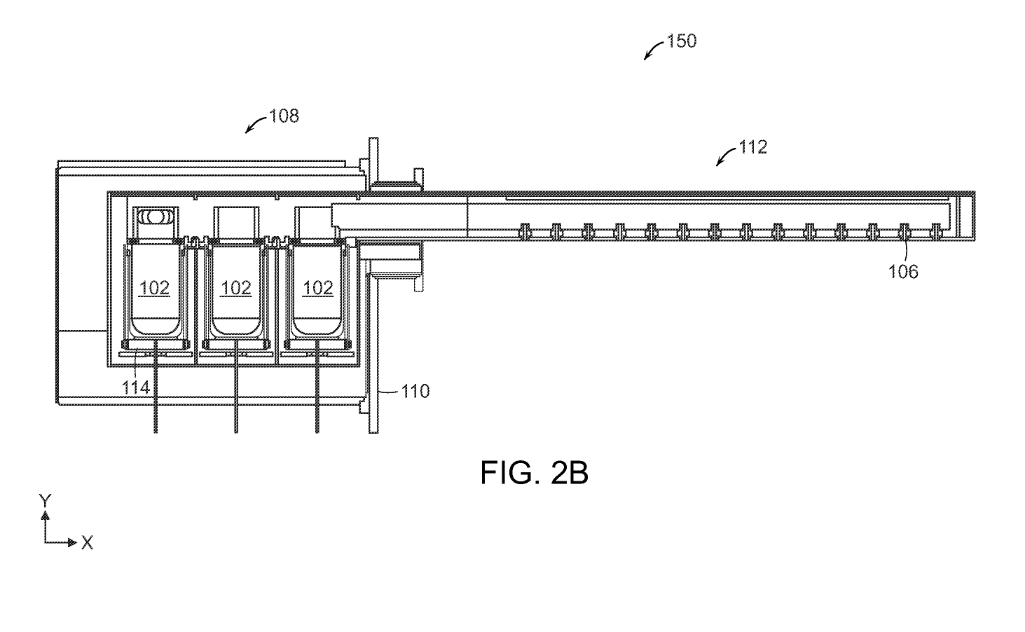

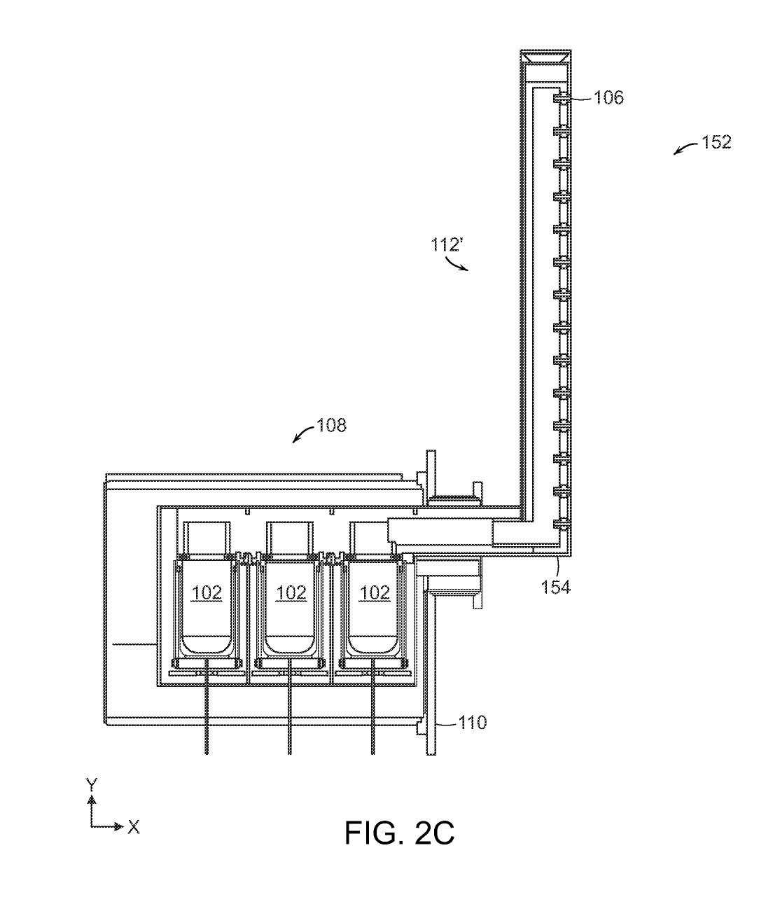

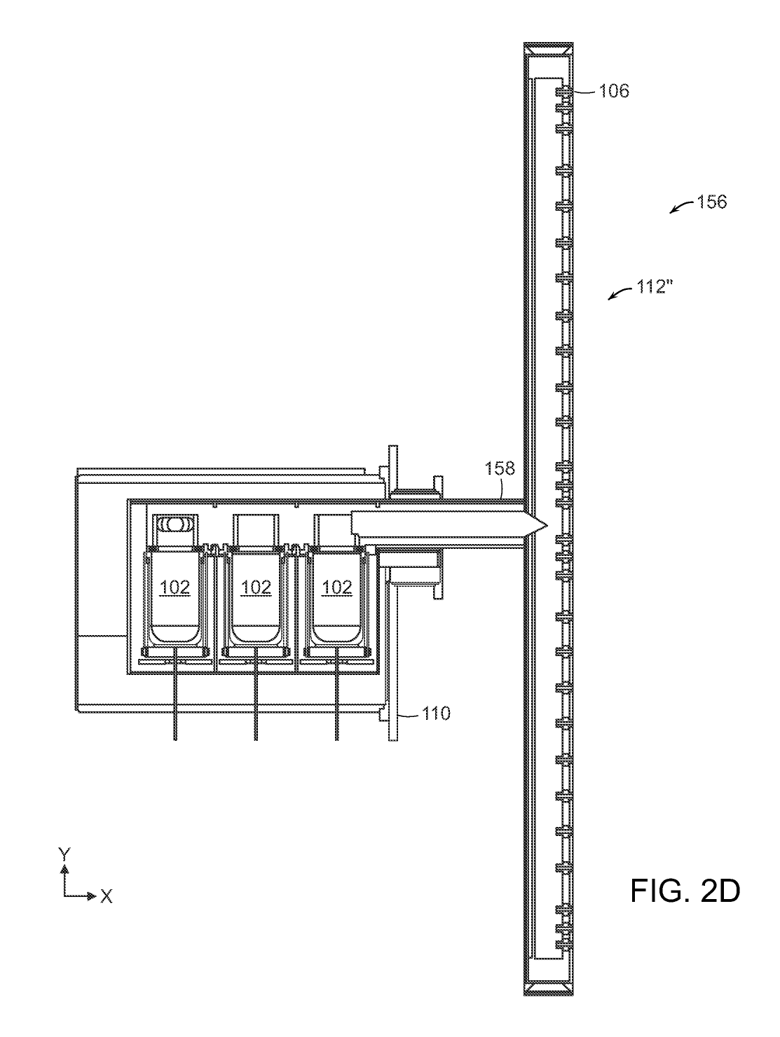

FIG. 2A illustrates a cross-sectional view of the linear deposition source 100 according to the present invention with the plurality of nozzles 106 positioned so that they evaporate deposition material in an upward direction. One feature of the linear deposition source of the present teaching is that the plurality of nozzles 106 can be positioned in any orientation relative to the plurality of crucibles 102. The heater for the plurality of conductance channels 104 is designed to prevent the evaporated source material from condensing independent of the orientation of the plurality of nozzles 106.

FIG. 2B illustrates a cross-sectional view of a linear deposition source 150 according to the present invention with the plurality of nozzles 106 positioned so that they evaporate deposition material in a downward direction. The linear deposition source 150 of FIG. 2B is similar to the linear deposition source 100 described in connection with FIG. 2A. However, the plurality of nozzles 106 is positioned with their outlet apertures facing downward in the direction of the plurality of crucibles 102.

FIG. 2C illustrates a cross-sectional view of a linear deposition source 152 according to the present invention with the body 112′ including the plurality of nozzles 106 positioned in a vertical direction. The linear deposition source 152 is similar to the linear deposition source 100 described in connection with FIG. 2A except that the linear deposition source 152 includes an angled coupling 154 that changes the orientation of the body 112′ relative to the normal direction from the sealing flange 110. One skilled in the art will appreciate that the angled coupling 154 can position the body 112′ at any angle relative to the normal direction of the sealing flange 110. Thus, one feature of the linear deposition source of the present teaching is that the body 112′ including the plurality of nozzles 106 can be positioned in any orientation relative to the housing 108 comprising the plurality of crucibles 102. The heater for the plurality of conductance channels 104 (FIG. 1) is designed to prevent the evaporated source material from condensing independent of the orientation of the body 112′.

FIG. 2D illustrates a cross-sectional view of another linear deposition source 156 according to the present invention with the body 112″ including the plurality of nozzles 106 positioned in a vertical direction. The linear deposition source 156 is similar to the linear deposition source 152 described in connection with FIG. 2C except that the linear deposition source 156 includes a T-shaped coupling 158 that changes the orientation of the body 112″ relative to the normal direction from the sealing flange 110. In the embodiment shown in FIG. 2D, the body 112″ extends in the vertical direction on both sides of the T-shaped coupling 158.

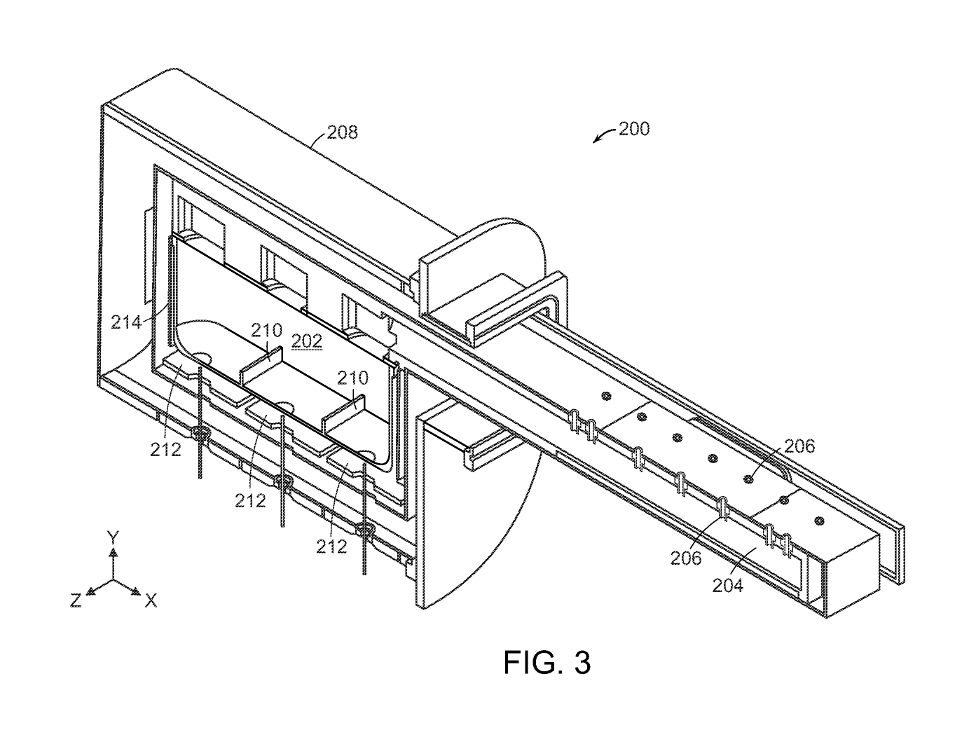

FIG. 3 illustrates a perspective cross-sectional view of a linear deposition 200 source according to the present invention that includes a single crucible 202 coupled to a plurality of conductance channels 204 and then to a plurality of nozzles 206 in a linear configuration. The linear deposition source 200 is similar to the linear deposition source 100 that is described in connection with FIGS. 1 and 2. However, the source 200 includes only one crucible 202. The single crucible 202 is positioned in a housing 208 as described in connection with FIG. 1.

The single crucible 202 can have a single compartment that is designed for one type of deposition source material. Such a crucible coupled to the plurality of conductance channels 204 will have relatively high deposition flux throughput. Alternatively, the single crucible 202 can have a plurality of partitions 210 that partially isolate sections of the crucible 202 where each of the partially isolated sections is dimensioned for positioning one of a plurality of deposition source materials. The plurality of deposition source materials can be the same material or can be a different material. In embodiments where the single crucible 202 includes a plurality of partially isolated sections, an input of each of the plurality of conductance channels 204 is positioned proximate one of the plurality of partially isolated sections.

A heater 212 is positioned in thermal communication with the single crucible 202. The heater 212 increases the temperature of the crucible 202 so that the crucible evaporates the at least one deposition material into the plurality of conductance channels 204. The heater 212 or a second heater is positioned in thermal communication with at least one of the plurality of conductance channels 204 in order to raise the temperature of the plurality of conductance channels 204 so that evaporated deposition source materials do not condense. Some heaters 212 can raise the temperature of at least one of the plurality of conductance channels 204 relative to another one of the plurality of conductance channels 204.

A heat shield 214 is positioned proximate to the crucible 202 and to the plurality of conductance channels 204 to provide at least partial thermal isolation of the crucible 202 and of the plurality of conductance channels 204. In some embodiments, the heat shield 214 is designed and positioned to control the temperature of one section of the crucible 202 relative to another section of the crucible 202. Also, in some embodiments, the heat shield 214 is designed and positioned in order to provide at least partial thermal isolation of at least one of the plurality of conductance channels 204 relative to at least one other conductance channels 204 so that different temperatures can be maintained in at least two of the plurality of conductance channels 204. In this embodiment, at least two of the plurality of conductance channels 204 can be shielded with heat shielding material having different thermal properties.

The plurality of nozzles 206 are coupled to the plurality of conductance channels 204. Evaporated deposition materials are transported from the single crucible 202 through the plurality of conductance channels 204 to the plurality of nozzles 206 where the evaporated deposition material is ejected from the plurality of nozzles 206 to form a deposition flux.

The linear sources of the present teaching are well suited for evaporating one or more different deposition source materials on large area workpieces, such as web substrates and rigid panel substrates. The linear geometry of the sources makes them well suited for processing wide and large area workpieces, such as web substrates and rigid panel substrates used for photovoltaic cells because the source can provide efficient and highly controllable vaporized material over a relatively large area.

One feature of the linear deposition sources of the present teaching is that they are relatively compact. Another feature of the linear deposition sources of the present teaching is that they uses common heaters and common heat shielding materials for each the plurality of deposition sources and for each of the plurality of conductance channels, which improves many equipment performance metrics, such as the size, equipment cost, and operating costs.

FIG. 4 illustrates a perspective cross-sectional view of a crucible 300 for the linear deposition source of the present teaching that is formed of two types of materials. The crucible 300 includes at least one crucible positioned inside another crucible. In the embodiment shown in FIG. 2, the crucible 300 includes an inner crucible 302 nested inside an outer crucible 304. In this crucible design, two types of materials can be used to contain the deposition material in order to improve the performance of the crucible. In other embodiments, at least one crucible is nested inside at least two other crucibles.

For example, in one embodiment, one or more of the plurality of crucibles 102 (FIG. 1) or crucible 202 (FIG. 3) is constructed with the inner crucible 302 formed of pyrolytic boron nitride and the outer crucible 304 formed of graphite. In this embodiment, the inner crucible 302 formed of the pyrolytic boron nitride contains the deposition source material. Pyrolytic boron nitride is a non-porous, highly inert, and an exceptionally pure material. In addition, pyrolytic boron nitride has a very high melting point, good thermal conductivity, and excellent thermal shock properties. These properties make pyrolytic boron nitride very well suited for directly containing most evaporation source materials. However, pyrolytic boron nitride is particularly brittle and, therefore, is easily damaged. The outer crucible 304 is formed of a material, such as graphite that is more durable, but still capable of high temperature operation. The more durable material protects the pyrolytic boron nitride from damage. In another embodiment, the inner crucible is formed of quartz and the outer crucible is formed of alumina. The combination of a quartz inner crucible and an alumina outer crucible is relatively inexpensive.

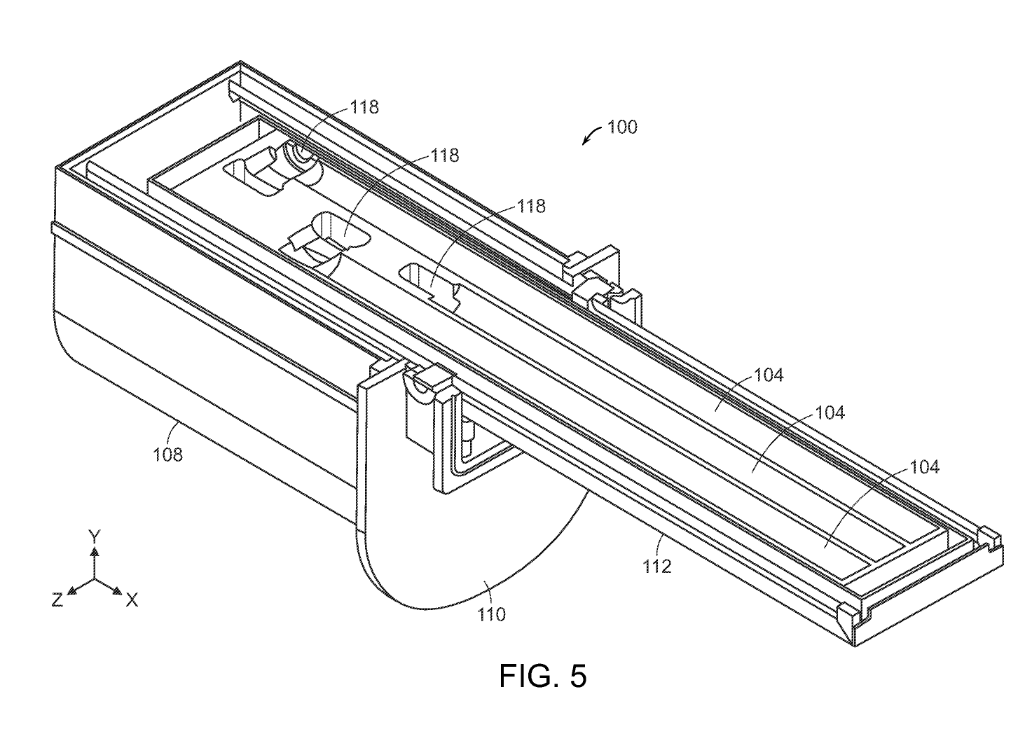

FIG. 5 illustrates a perspective top view of a portion of the linear deposition source 100 according to the present invention that shows the three conductance channels 104 coupled to three crucibles 102 in the housing 108. An input 118 of each of the three conductance channels 104 is coupled to an output of a respective one of the three crucibles 102. The three conductance channels 104 are designed so that there is no significant intermixing of evaporated materials from any of the three crucibles 102 while the evaporated materials are being transported through the plurality of conductance channels 104. In many deposition processes, it is important to substantially prevent intermixing of deposition materials in order to prevent reactions of two or more deposition materials from occurring before the deposition material reaches the surface of the substrate being processed.

FIG. 6A is a perspective view of a portion of a resistive crucible heater 400 for the linear deposition source of the present invention that shows the inside and three sides of the crucible heater 400 where the crucible 102 (FIG. 1) is positioned. In various embodiments, the crucible heater 400 can be fixed in the housing 108 (FIG. 1) or can removably attached to the housing 108. The crucible heater 400 includes a plurality of resistive heating elements 402 on the bottom and sides that surround the crucible 102. In the embodiment shown in FIG. 6A, the resistive heating elements 402 are a plurality of spaced apart graphite bus bars 402 that are linear strips of graphite material. Support rods 404 structurally connect the graphite bus bars 402 together and also electrically insulating the bus bars 402. The resistive heating elements 402 can include serpentine graphite springs positioned between opposite ends of the heating elements 402. Electrical wires are fed through the housing 108 of the source 100 to connect the graphite bus bars 402 to a power supply (not shown). The graphite bus bars 402 include screws 406 for securely attaching the electrical wires.

FIG. 6B is a perspective view of an outside of one of the plurality of crucible heaters 400 for heating each of the plurality of crucibles 102 (FIG. 1). The perspective view shown in FIG. 6B is similar to the perspective view shown in FIG. 6A, but it shows all four sides of the crucible heater 400.

FIG. 7A is a side view of a linear deposition source 100 according to the present invention that shows conductance channel heaters for heating the plurality of conductance channels 104 (FIG. 1). FIG. 7B shows a perspective view of the rods 130 comprising the conductance channel heaters. FIG. 7C illustrates a perspective view of the body 112 of a linear deposition source 100 according to the present invention that shows a coupling 132 which joins the end of the rods 130 to the body 112.

Referring to FIGS. 1, 7A, 7B, and 7C, the rods 130 are positioned proximate to the conductance channels 104 in the longitudinal direction of the body 112 along the length of the conductance channels 104. The rods 130 can be formed of any type of high temperature resistive material such as graphite, silicon carbide, refractory materials, or other very high melting point materials. The rods 130 are electrically connected to an output of a power supply (not shown) that generates a current which flows through the rods 130, thereby increasing the temperature of the rods 130. The rods 130 can be electrically connected to the output of the power supply using a spring or a wire harness that provides for enough movement to allow for thermal expansion of the rods 130 during normal operation. Heat generated in the rods 130 by current from the power supply radiates into the conductance channels 104, thereby raising the temperature of the conductance channels 104 so that evaporated source material transporting through the plurality of conductance channels 104 does not condense.

FIG. 7A also shows a plurality of coupling 152 that attach segments of the rods 130 together. In some embodiments, the length of the body 112 is so long that coupling multiple segments of rods 130 together is more cost effective, reliable, and easier to manufacture. One skilled in the art will appreciate that there are numerous types of couplings that can be used to couple together multiple segments of rods 130. For example, a threaded coupling can be used to couple two rod segments together. The coupling 132 provide a continuous electrical connection with a relatively constant resistance through the entire length of the rods 130.

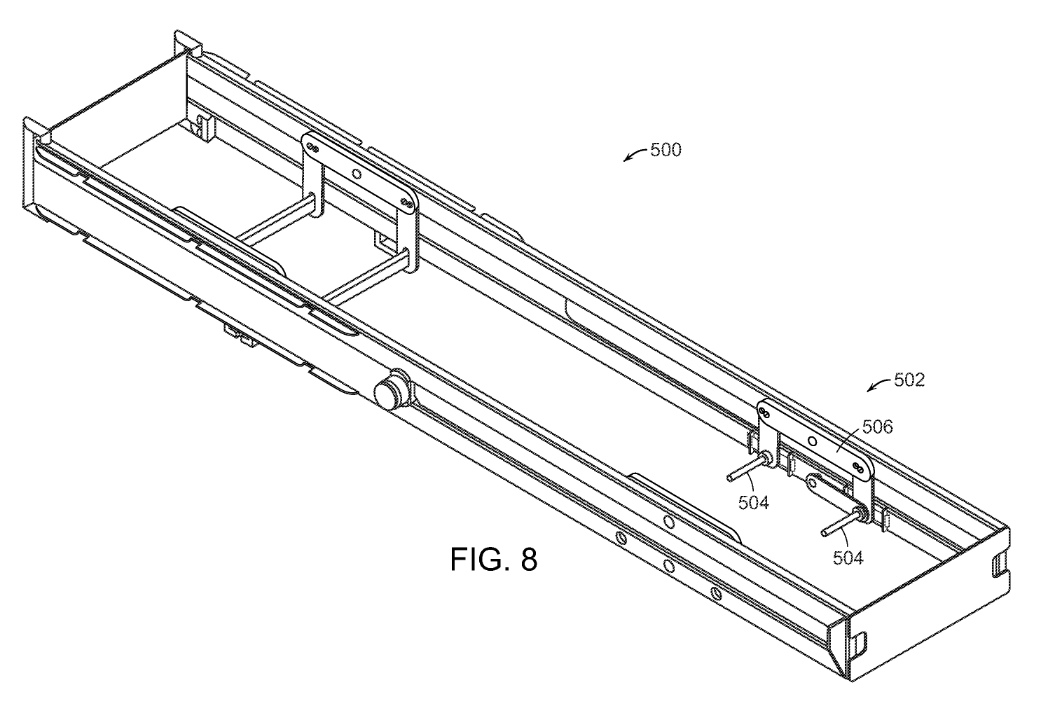

FIG. 8 illustrates the frame 500 of the body 112 (FIG. 1) that includes an expansion link 502. Referring to FIGS. 1, 7A, and 8, the plurality of conductance channels 104 is removed from the space inside the frame 500 of the body 112 in order to view the expansion link 502. The expansion link 502 is sometimes used because the body 112 experiences significant thermal expansion and contraction during normal operation. The coefficient of thermal expansion of the rods 130 and the plurality of conductance channels 104 can be significantly different from the coefficient of thermal expansion of the frame 500 and other components in the body 112. In addition, there may be significant temperature differences between the frame 500 and other components in the body 112, such as the rods 130 and the plurality of conductance channels 104. Consequently, it is desirable for the frame 500 to expand and contract freely relative to other components in the body 112, such as the plurality of conductance channels 104 and the rods 130.

The expansion link 500 shown in FIG. 8 is one of numerous types of expansion links that can be used in the frame 500. In the embodiment shown in FIG. 8, the expansion link 500 is attached to two sections of the frame 500 with pins 504 or other types of fasteners. When the expansion link 502 is expanded, the linking section 506 expands, thereby creating space in the frame 500 for components in the body 112 that are expanding faster than the frame 500. Alternatively, when components in the body 112 are contracting faster than the frame 500, the linking section 506 folds, thereby reducing space in the frame 500 to match the space of the contracting body 112.

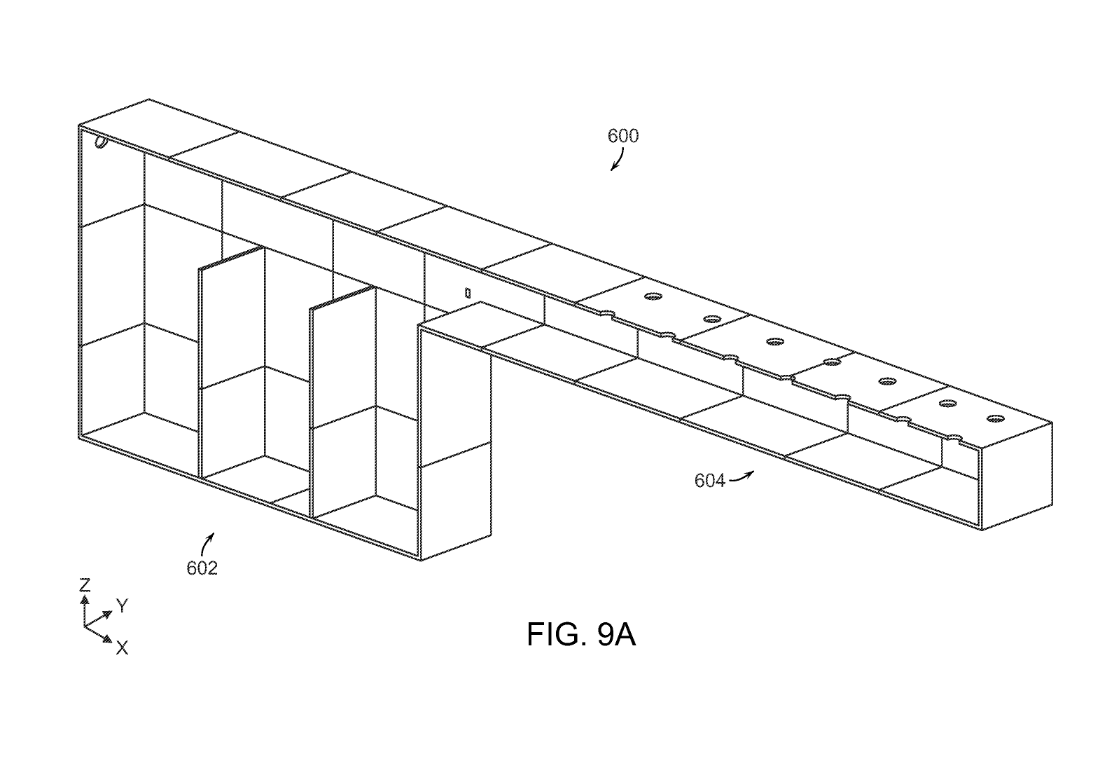

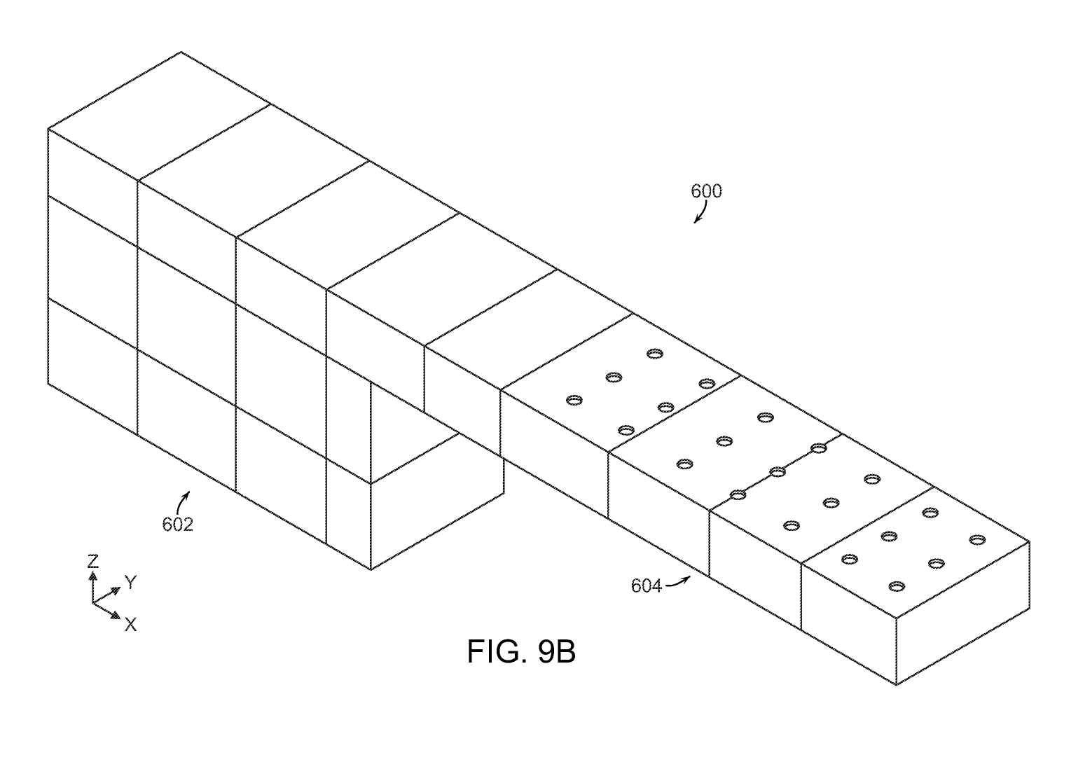

FIG. 9A is a perspective cross-sectional view of a heat shield 600 for the plurality of crucibles 102 (FIG. 1) and for the plurality of conductance channels 104 of a linear deposition source according to the present teaching. FIG. 9B is a full perspective view of the heat shield 600 shown in FIG. 9A. One skilled in the art will appreciate that the heat shield 600 can be made of any one of numerous types of heat shielding material. For example, in one embodiment, the heat shield 600 is formed of a carbon fiber carbon composite material.

Referring to FIGS. 1, 9A and 9B, a first section 602 of the heat shield 600 is positioned proximate to each of the plurality of crucibles 102 in order to provide at least partial thermal isolation of each of the plurality of crucibles 102. The first section 602 of the heat shield 600 isolates the individual crucibles 102 so that significantly different crucible temperatures can be maintained during processing if necessary. Maintaining significantly different crucible temperatures is important for some deposition processes because each of the plurality of crucibles 102 can then be heated to its optimum temperature for the particular source material. Heating the crucibles 102 to their optimum temperature for the particular source material reduces negative heating effects, such as spitting of deposition material. In addition, heating the crucibles 102 to their optimum temperature for the particular source material can significantly reduce the operating costs of the deposition source.

In various other embodiments, the first section 602 of the heat shield 600 can include a plurality of separate heat shields where a respective one of the plurality of separate heat shields 600 surrounds a respective one of the plurality of crucibles 102. Each of the plurality of separate heat shields can be the same or can be a different heat shield. For example, crucibles that are used to heat higher temperature deposition source materials can be formed of different or thicker heat shielding materials with different thermal properties.

The second section 604 of the heat shield 600 is positioned proximate to the plurality of conductance channels 104 in order to provide at least partial thermal isolation of the plurality of conductance channels 104 from the plurality of crucibles 102. Each of the plurality of conductance channels 104 can be shielded by a separate heat shield or a single heat shield can be used. In some embodiments, the second section 604 of the heat shield 600 is positioned in order to provide at least partial thermal isolation of at least one of the plurality of conductance channels 104 relative to at least one other conductance channel. In other words, the design and positioning of the second section 604 of the heat shield 600 can be chosen to allow a different operating temperature in at least one of the plurality of conductance channels 104 relative to at least one other of the plurality of conductance channels 104. In these embodiments, at least two of the plurality of conductance channels 104 can be shielded with heat shielding material having different thermal properties. For example, at least two of the plurality of conductance channels 104 can be shielded by different heat shielding materials, different heat shielding thickness, and/or different proximities of the heat shielding material to particular conductance channels.

The heat shield 600 is exposed to very high temperatures during normal operation. Some heat shields according to the present teachings are constructed with at least one surface being formed of a low emissivity material or having a low emissivity coating that reduces the emission of thermal radiation. For example, an inner or outer surface of the heat shield 600 can be coated with a low emissivity coating or any other type of coating that reduced heat transfer. Any such coating is usually designed to maintain constant emissivity over the operational lifetime of the source.

The heat shield 600 also expands and contracts at different rates compared to the housing 108 and the body 112 and to components in the housing 108 and body 112. In one embodiment, the heat shield 600 is movably attached to at least one of the housing 108 and the frame 500 (FIG. 8) of the body 112 so that it can move relative to at least one of the housing 108 and the frame 500 during normal operation. In some embodiments, an expansion link is used to allow the heat shield 600 to expand and contract relative to other source components. Furthermore, in some embodiments, the heat shield 600 includes a plurality of layers of heat shielding materials that are tolerant to thermal expansion and contraction. For example, a plurality of heat shielding tiles can be used to increase the tolerance to thermal expansion and contraction.

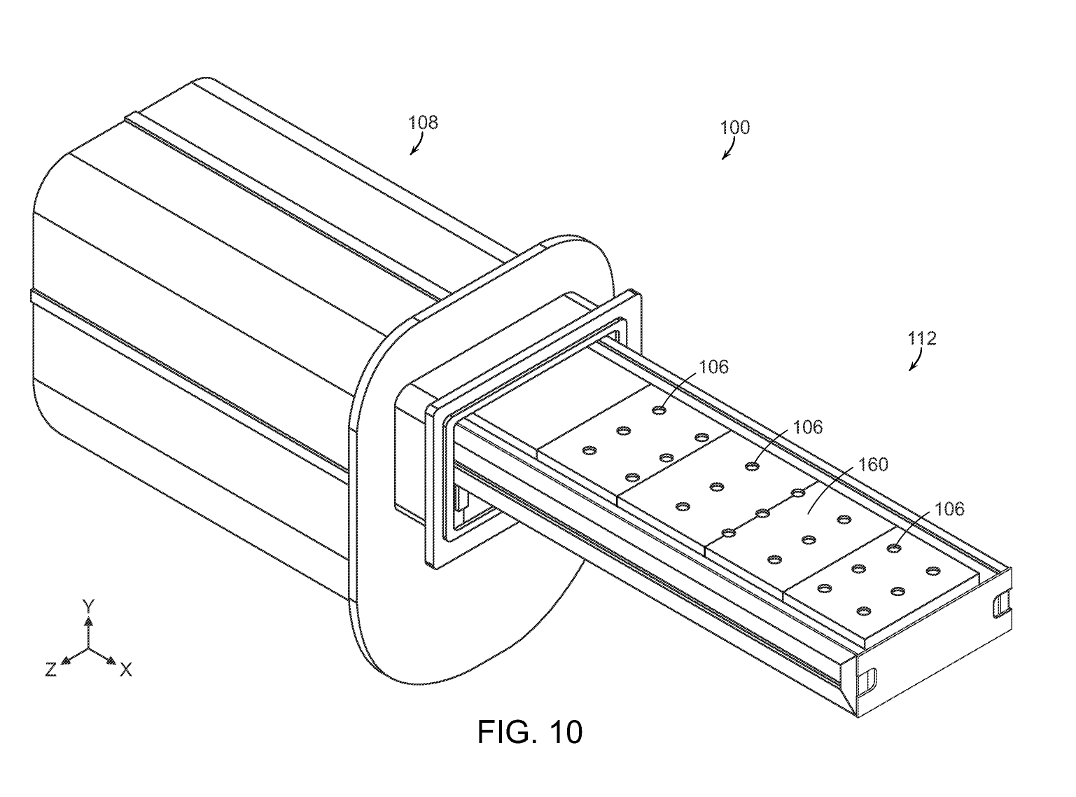

FIG. 10 illustrates a top perspective view of a deposition source 100 according to the present teaching that shows the plurality of nozzles 106 in the body 112 for emitting evaporated materials onto substrates or other workpieces. An input of each of the plurality of nozzles 106 is coupled to an output of a respective one of the plurality of conductance channels 104 as described in connection with FIG. 5. The evaporated deposition materials are transported without intermixing from the plurality of crucibles 102 through the plurality of conductance channels 104 to the plurality of nozzles 106 where the evaporated deposition material is ejected from the plurality of nozzles 106 to form a deposition flux.

The source 100 shown in FIG. 10 illustrates seven groups of nozzles 106 where each group includes three nozzles. One skilled in the art will appreciate that a deposition source according to the present invention can include any number of groups of nozzles and any number of nozzles within each group. In various embodiments, the spacing of the plurality of nozzles 106 can be uniform or non-uniform. One aspect of the present teaching is that the plurality of nozzles 106 can be non-uniformly spaced in order to achieve certain process goals. For example, in one embodiment, the spacing of the plurality of nozzles 106 is chosen to improve uniformity of the deposition flux. In this embodiment, the spacing of the nozzles 106 near the edge of the body 112 is closer than the spacing of the nozzles 106 proximate to a center of the body 112 as shown in FIG. 10 in order to compensate for reduced deposition flux near the edges of the body 112. The exact spacing can be chosen so that the source 100 generates a substantially uniform deposition material flux proximate to the substrate or workpiece.

In some embodiments, the spacing of the plurality of nozzles 106 is chosen to obtain high material utilization in order to lower the operating cost of the deposition source 100 and to increase the process time and availability between service intervals. Also, in some embodiments, the spacing of the plurality of nozzles 106 is chosen to provide a desired overlap of deposition flux from the plurality of nozzles 106 in order to achieve a predetermine mixture of evaporated materials.

In one embodiment, at least some of the plurality of nozzles 106 is positioned at an angle relative to the normal angle from the top surface 160 of the conductance channels 104 in order to achieve certain process goals. For example, in one embodiment, at least one of the plurality of nozzles 106 is positioned at an angle relative to the normal angle from the top surface 160 of the conductance channels 104 that is chosen to provide a uniform deposition flux across the surface of the substrates or workpieces being processed. Also, in some embodiments, at least one of the plurality of nozzles 106 is positioned at an angle relative to the normal angle from the top surface 160 of the conductance channels 104 that is chosen to provide a desired overlap of deposition flux from the plurality of nozzles 106 to achieve a predetermine mixture of evaporated materials.

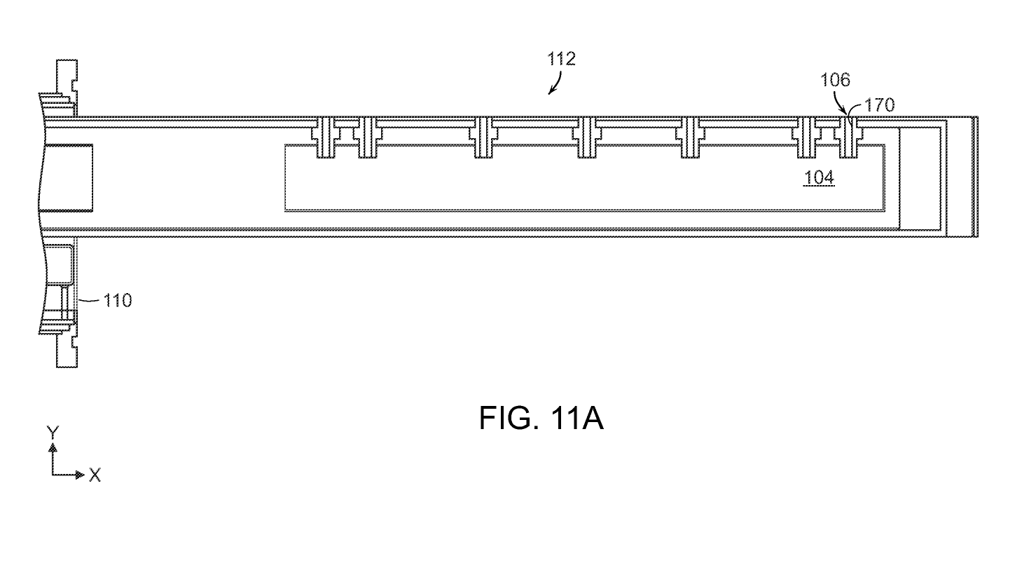

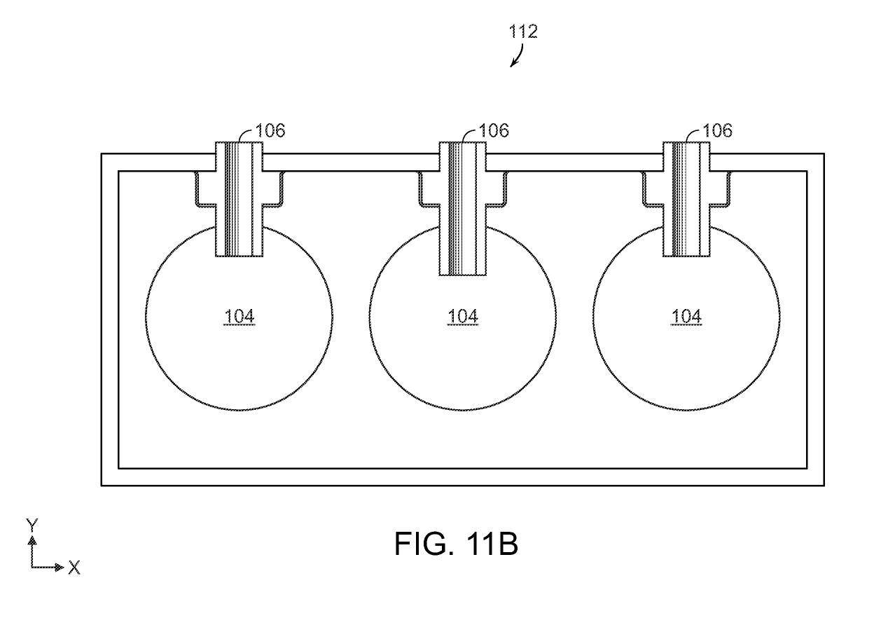

FIG. 11A illustrates a cross-sectional view of the body 112 of the deposition source 100 according to the present teaching that shows a column of nozzles 106 coupled to a conductance channel 104 with tubes 170 that control the flow of deposition material to the nozzles 104. In some embodiments, the emissivity at the top of the tubes 170 is lower than the emissivity at the bottom of the tubes 170. The dimensions of the tubes 170, such as the length and diameter of the tubes 170, determine the amount of deposition material that is supplied from the conductance channel 104 to the corresponding nozzles 106. In addition, the positioning of the tubes 170, such as the distance that the tubes 170 are positioned in the conductance channel 104, also determines the amount of deposition material that is supplied from the conductance channel 104 to the corresponding nozzle 106.

For example, changing the diameter of the tubes 170 changes the distribution deposition flux pattern emanating from the nozzle 106. The length of the tubes 170 is generally chosen to match the overall flow resistance and design of the tubes 170. In some embodiments, longer tubes 170 that penetrate further into the conductance channel 104 will supply less deposition material to the corresponding nozzle 106. In various embodiments, the geometry and position of particular tubes 170 can be the same or can be different. In one embodiment, at least two of the plurality of tubes 170 can have different lengths and/or different geometries in order to obtain a particular conductance through each of the plurality of tubes 170 that achieves certain process goals. For example, tubes 170 with different dimensions can be used to compensate for pressure differentials in the source 100 from the body 112 near the sealing flange 110 to the end of the body 112.

Thus, one feature of the deposition source 100 of the present invention is that the geometry and positioning of the tubes 170 can be chosen to precisely control the quantity of evaporated material supplied to each of the plurality of nozzles 106 without changing the distribution of the evaporated material emanating from the plurality of nozzles 106. For example, a geometry and position of particular tubes 170 can be chosen to achieve certain process goals, such as a predetermined deposition flux from particular nozzles or from the plurality of nozzles 106.

In some embodiments, at least one of the plurality of nozzles 106 extends above the top surface 160 of the plurality of conductance channels 104 in order to prevent vapor condensation and material accumulation building up over time. Nozzles can also be positioned to achieve a desired deposition flux distribution pattern. Individual nozzle heaters can be positioned proximate to one or more of the plurality of nozzles 106 to control the temperature of the vaporized material emanating from the nozzles 106 to prevent condensation and material accumulation. In other embodiments, at least one of the plurality of nozzles 106 is positioned below the top surface 160 of the plurality of conductance channels 104 in order to conduct the desired amount of heat from the heater and the plurality of conductance channels 104 and/or to achieve a desired deposition flux distribution pattern.

FIG. 11B illustrates a cross-sectional view of the plurality of conductance channels 104 of the deposition source 100 according to the present teaching that shows a row of nozzles 106 coupled to the plurality of conductance channel 104 with tubes 170 that control the flow of deposition material to the nozzles 104. FIG. 11B shows three conductance channels with tubes. One aspect of the present teachings is that the nozzles 106 are heated by the conductance channel heaters (rods 130 in FIGS. 7A-C) and by the associated conductance channel 104.

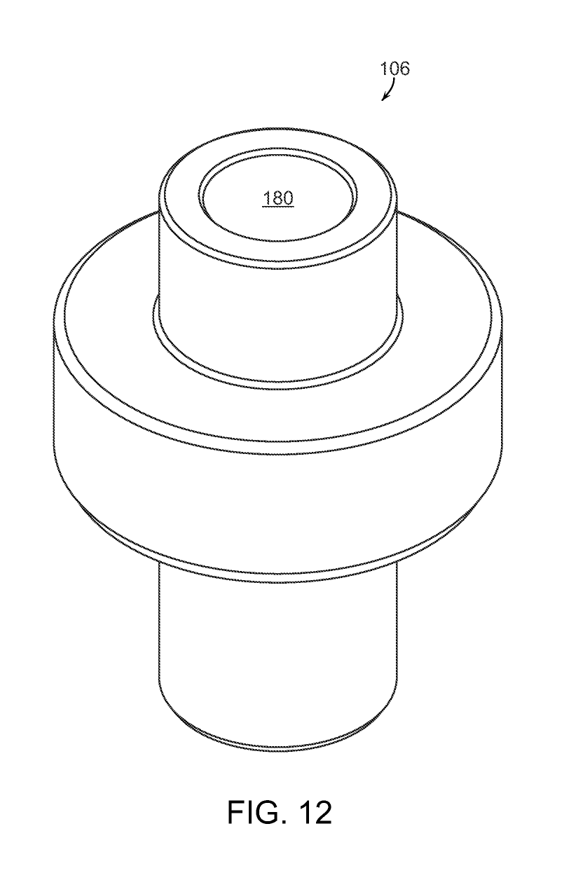

FIG. 12 illustrates a perspective view of a nozzle 106 comprising one of the plurality of nozzles 106 for the linear source 100 according to the present teaching. The nozzle 106 is designed so that it provides the required heat conduction to prevent the evaporated source material from condensing. The nozzle 106 can be formed of a material having a thermal conductivity that results in a uniform operating temperature, thereby reducing spitting of deposition materials. For example, the nozzle can be formed of graphite, silicon carbide, a refractory material, or other very high melting point materials. In some embodiments, the nozzle 106 is designed to reduce thermal gradients through the nozzle 106. In addition, the nozzle 106 can be designed to minimize radiation losses.

In some embodiments, the nozzle 106 can include a tapered outside surface. Also, in some embodiments, the nozzle 106 is tapered on the inside. In some embodiments, the surface of the aperture 180 has a low emissivity coating that reduces thermal emission, thereby reducing any condensation in the nozzle 106. In other embodiments, the nozzle 106 is formed of a material with a low emissivity.

The nozzle 106 includes an aperture 180 for passing the evaporated source material from the associated conductance channel 104. The aperture 180 is designed to eject the desired plume. A generally round aperture 108 is shown in the nozzle 106 of FIG. 12. However, it should be understood that any one of numerous aperture shapes can be used in the nozzle 106 to achieve the desired processing goals. For example, the aperture 180 can be round, oval, rectangle, square, or a slit. In addition, the outlet of the aperture 180 is shown with a radius shape. However, it should be understood that the aperture 180 can use any one of numerous outlet shapes to achieve the desired processing goals. For example, the outlet shape can be chamfered, radiused or sumo style (i.e. reverse draft or other type of restricted nozzle shape).

In some embodiments, at least one of the plurality of nozzles 106 has an aperture 180 that is shaped to pass a non-uniform deposition flux. In these embodiments, at least some of the plurality of apertures 180 can be shaped to pass non-uniform deposition flux that combines to form a desired deposition flux pattern. For example, the desired combined deposition flux pattern can be a uniform deposition flux pattern over a predetermined area.

In operation, a method of generating deposition flux from multiple deposition sources includes heating a plurality of crucibles 102 that each contains a deposition source material so that each of the plurality of crucibles 102 evaporates deposition material. The method can include independently controlling separate crucible heaters to achieve different crucible temperatures for each deposition source material. The method can also include shielding each of the plurality of crucibles 102 so that different temperatures can be maintained in particular crucibles.

Deposition material from each of the plurality of crucibles 102 transports through respective conductance channels 104 in the body 112 without intermixing the deposition materials evaporated from any of plurality of crucibles 102. The conductance channels 104 are heated so that the vaporized deposition material does not condense before emanating from the nozzles 106. The conductance channels 104 can be separately heated so as to achieve different temperatures for at least two of the plurality of conductance channels 104. Each of the plurality of conductance channels 104 can be shielded so that different temperatures can be maintained in different conductance channels 104. Many methods include providing movable components and space for thermal expansion of heater and heat shielding material proximate to the plurality of crucibles 102 and proximate to the plurality of conductance channels 104.

Evaporated deposition material is transported from each of the plurality of conductance channels 104 to respective ones of the plurality of nozzles 106. In various embodiments, the evaporated deposition material is transported from each of the plurality of conductance channels 104 to a respective one of the plurality of nozzles 106 through a respective one of a plurality of tubes 170 or other structures that control the flow of the deposition material. In various embodiments of the method of the present invention, the flow of the deposition material through the plurality of nozzles 106 is controlled by using tubes with varying length, geometry, and/or position of the tube inlet relative to the conductance channel 104. The length, geometry, and/or position of the tube inlet relative to the conductance channel 104 are chosen to achieve certain process goals such as uniform deposition flux and/or high deposition material utilization.

The plurality of nozzles 106 then passes the evaporated deposition material, thereby forming a deposition flux. The method can include selecting a spacing of the plurality of nozzles 106 to achieve certain process goals, such as uniform deposition flux from the plurality of nozzles 106 and/or high deposition material utilization.

### EQUIVALENTS

While the applicant's teaching are described in conjunction with various embodiments, it is not intended that the applicant's teaching be limited to such embodiments. On the contrary, the applicant's teaching encompass various alternatives, modifications, and equivalents, as will be appreciated by those of skill in the art, which may be made therein without departing from the spirit and scope of the teaching.

What is claimed is:

1. A deposition source comprising:
a) a plurality of crucibles for containing deposition material;
b) a body comprising a plurality of conductance channels, an input of each of the plurality of conductance channels being coupled to an output of a respective one of the plurality of crucibles;
c) a heater that is positioned in thermal communication with the plurality of crucibles and the plurality of conductance channels, the heater increasing a temperature of the plurality of crucibles so that each of the plurality of crucibles evaporates the deposition material into the plurality of conductance channels;
d) a heat shield that provides at least partial thermal isolation for at least one of the plurality of crucibles; and
e) a plurality of nozzles, an input of each of the plurality of nozzles being coupled to an output of one of the plurality of conductance channels, evaporated deposition materials being transported from the plurality of crucibles through the plurality of conductance channels to the plurality of nozzles where the evaporated deposition material is ejected from the plurality of nozzles to form a deposition flux.

2. The deposition source of claim 1 wherein at least some of the plurality of crucibles comprises an inner crucible positioned inside an outer crucible.

3. The deposition source of claim 1 wherein the plurality of crucibles comprises a first crucible containing Cu, a second crucible containing In, and a third crucible containing Ga.

4. The deposition source of claim 1 wherein each of the plurality of crucibles contains the same deposition material.

5. The deposition source of claim 1 wherein the heater comprises at least one of an RF induction heater, a resistive heater, and an infrared heater.

6. The deposition source of claim 1 wherein the heater comprises a plurality of individually controllable heaters wherein a respective one of the plurality of heaters is in thermal communication with a respective one each of the plurality of crucibles.

7. The deposition source of claim 1 wherein the heater raises temperatures of each of the plurality of conductance channels above the condensation point of the deposition materials.

8. The deposition source of claim 1 wherein the heater controls a temperature of one of the plurality of conductance channels relative to another one of the plurality of conductance channels.

9. The deposition source of claim 1 wherein the heat shield provides at least partial thermal isolation for at least one of the plurality of conductance channels.

10. The deposition source of claim 1 wherein the heat shield comprises a plurality of heat shielding tiles.

11. The deposition source of claim 1 wherein the heat shield comprises a plurality of layers of heat shielding material.

12. The deposition source of claim 1 wherein the heat shield is attached to the body with an expansion link.

13. The deposition source of claim 1 wherein the heat shield comprises at least one surface with a low emissivity.

14. The deposition source of claim 1 wherein the heat shield comprises a plurality of heat shields wherein a respective one of the plurality of heat shields surrounds a respective one of the plurality of crucibles.

15. The deposition source of claim 1 wherein the heat shield surrounds the plurality of conductance channels.

16. The deposition source of claim 1 wherein the heat shield is positioned so that at least one of the plurality of conductance channels is at a different operating temperature than at least one other of the plurality of conductance channel.

17. The deposition source of claim 1 wherein a spacing of the plurality of nozzles is non-uniform.

18. The deposition source of claim 1 wherein a spacing of the plurality of nozzles is closer proximate to an edge of the body than a spacing of the plurality of nozzles proximate to a center of the body.

19. The deposition source of claim 1 wherein a spacing of the plurality of nozzles is chosen to achieve substantially uniform deposition material flux.

20. The deposition source of claim 1 wherein a spacing of the plurality of nozzles is chosen to increase utilization of deposition material.

21. The deposition source of claim 1 wherein a spacing of the plurality of nozzles is chosen to provide a desired overlap of deposition flux from the plurality of nozzles.

22. The deposition source of claim 1 wherein at least one of the plurality of nozzles is positioned at an angle relative to a normal angle to a top surface of the plurality of conductance channels that is chosen to provide a desired overlap of deposition flux from the plurality of nozzles.

23. The deposition source of claim 1 wherein at least one of the plurality of nozzles comprises an aperture that is shaped to pass a non-uniform deposition flux.

24. The deposition source of claim 1 wherein at least one of the plurality of nozzles comprises a low emissivity coating.

25. The deposition source of claim 1 wherein at least one of the plurality of nozzles is formed of a material having a thermal conductivity that results in a uniform operating temperature, thereby reducing spitting of deposition materials from the plurality of nozzles.

26. The deposition source of claim 1 wherein at least one of the plurality of nozzles comprises a tube that is positioned proximate to the conductance channel, the tube restricting the amount of deposition material supplied to the corresponding nozzle.

27. The deposition source of claim 26 wherein a length the tube is chosen to achieve a predetermined deposition flux through a corresponding one of the plurality of nozzles.

28. The deposition source of claim 1 wherein at least one of the plurality of nozzles comprises a tube that is positioned at least partially into the conductance channel, the tube restricting the amount of deposition material supplied to the corresponding nozzle.

29. The deposition source of claim 1 wherein at least two of the plurality of nozzles comprise a tube that restricts an amount of material supplied to corresponding nozzles, a length of the tube corresponding to one of the plurality of nozzles being different from a length of the tube corresponding to at least one other of the plurality of nozzles.

30. The deposition source of claim 1 wherein at least two of the plurality of nozzles comprise a tube that restricts an amount of material supplied to corresponding nozzles, a geometry of the tube corresponding to one of the plurality of nozzles being different from a geometry of the tube corresponding to at least one other of the plurality of nozzles.

31. The deposition source of claim 1 wherein a top of at least one of the plurality of nozzles extends above the plurality of conductance channels.

32. The deposition source of claim 1 wherein a top of at least one of the plurality of nozzles extends below the plurality of conductance channels.

33. The deposition source of claim 1 further comprising fluid cooling channels positioned proximate to at least one edge of the body.

34. A method of generating deposition flux, the method comprising:
a) heating a plurality of crucibles that each contain a deposition material so that each of the plurality of crucibles evaporate deposition material that transports through one of a plurality of conductance channels in a body; and
b) transporting the evaporated deposition material from each of the plurality of conductance channels to one of the plurality of nozzles, the plurality of nozzles passing evaporated deposition material, thereby forming a deposition flux.

35. The method of claim 34 further comprising transporting the evaporated deposition material from each of the plurality of conductance channels through a respective one of a plurality of tubes to a respective one of the plurality of nozzles.

36. The method of claim 35 further comprising selecting dimensions of at least one of the plurality of tubes to achieve a uniform deposition flux from the plurality of nozzles.

37. The method of claim 35 further comprising selecting dimensions of at least one of the plurality of tubes to achieve a high deposition material utilization.

38. The method of claim 34 further comprising independently controlling a temperature of at least some of the plurality of crucibles and the plurality of conductance channels.

39. The method of claim 34 further comprising shielding heat generated by at least one of the plurality of crucibles to control a temperature of at least one crucible relative to a temperature of at least one other crucible.

40. The method of claim 34 further comprising shielding heat generated by at least one of the plurality of conductance channels to control a temperature of at least one conductance channel relative to a temperature of at least one other conductance channel.

41. The method of claim 34 further comprising providing space for thermal expansion of heat shielding material proximate to at least one of the plurality of crucibles and the plurality of conductance channels.

42. A deposition source comprising:
a) a crucible that contains at least one deposition material;
b) a body comprising a plurality of conductance channels that are coupled to the crucible;
c) a heater that is positioned in thermal communication with the crucible, the heater increasing a temperature of the crucible so that the crucible evaporates the at least one deposition material into the plurality of conductance channels;
d) a heat shield that provides at least partial thermal isolation for the crucible; and
e) a plurality of nozzles that are coupled to the plurality of conductance channels, evaporated deposition materials being transported from the crucible through the plurality of conductance channels to the plurality of nozzles where the evaporated deposition material is ejected from the plurality of nozzles to form a deposition flux.

43. The deposition source of claim 42 wherein the crucible comprises a plurality of partially isolated sections, each of the partially isolated sections being dimensioned for positioning one of a plurality of deposition materials.

44. The deposition source of claim 43 wherein at least two of the plurality of partially isolated sections contain different deposition materials.

45. The deposition source of claim 43 wherein an input of each of the plurality of conductance channels is positioned proximate one of the plurality of partially isolated sections.

46. The deposition source of claim 43 wherein the heat shield provides thermal isolation that controls a temperature of one section of the crucible relative to another section of the crucible.

47. The deposition source of claim 42 wherein the heater is positioned in thermal communication with at least one of the plurality of conductance channels, the heater raising the temperature of at least one of the plurality of conductance channels relative to another one of the plurality of conductance channels.

48. The deposition source of claim 42 wherein the heat shield provides thermal isolation for at least one of the plurality of conductance channels.
